(19) United States
(12) Patent Application Publication
(10) Pub. No.: US 2007/0264524 A1
(43) Pub. Date: Nov. 15, 2007

(54) Use of Metallocene Complexes of Metals in the 4th Sub-Group of the Period Table as Triple Emitters in Organic Light-Emitting Diodes (Oleds)

(75) Inventors: Thomas Gessner, Heidelberg (DE); Martin Konemann, Mannheim (DE); Hans-Werner Schmidt, Bayreuth (DE); Mukundan Thelakkat, Bayreuth (DE); Markus Baete, Kulmain (DE)

Correspondence Address: OBLON, SPIVAK, MCCLELLAND MAIER & NEUSTADT, P.C., 1940 DUKE STREET, ALEXANDRIA, VA, 22314, US

(73) Assignee: BASF Aktiengesellschaft, Ludwigshafen (DE)

(21) Appl. No.: 11/547,175

(22) PCT Filed: Apr. 4, 2005
(86) PCT No.: PCT/EP05/03516

§ 371 Date: Oct. 2, 2006

(30) Foreign Application Priority Data
Apr. 8, 2004 (DE) 10 2004 018 145.4

(51) Int. Cl. H01L 29/861

(52) U.S. Cl. 428/690; 257/E51.026

(57) ABSTRACT

The present invention relates to the use of metallocene complexes of metals of transition group 4 of the Periodic Table as emitter molecules in organic light-emitting diodes (OLEDs), the use of the metallocene complexes as light-emitting layer in OLEDs, a light-emitting layer comprising at least one metallocene complex, an OLED comprising this light-emitting layer and devices comprising an OLED according to the invention.

The present invention relates to the use of metallocene complexes of metals of transition group 4 of the Periodic Table as emitter molecules in organic light-emitting diodes (OLEDs), the use of the metallocene complexes as light-emitting layer in OLEDs, a light-emitting layer comprising at least one metallocene complex, an OLED comprising this light-emitting layer and devices comprising an OLED according to the invention.

Organic light-emitting diodes (OLEDs) exploit the ability of materials to emit light when they are excited by an electric current. OLEDs are of particular interest as alternatives to cathode ray tubes and liquid crystal displays for producing flat visual display units (VDUs). Owing to their very compact construction and their intrinsically low power consumption, devices comprising OLEDs are particularly useful for mobile applications, for example for applications in celltelephones, laptops, etc.

Numerous materials which emit light on excitation by electric current (electroluminescence) have been proposed.

The photoluminescence of specific zirconium complexes is described in the prior art mentioned below. There is no prior art known in respect of electroluminescence of zirconocene or hafnocene complexes, as is required for use in organic light-emitting diodes (OLEDs).

Vogler et al., Eur. J. Inorg. Chem. 1998, 1863 to 1865, report a study of ligand-ligand charge transfer in (2,2′-bisquinolinolato)bis(cyclopentadienyl)-zirconium(IV). This complex displays emission in the visible region of the electromagnetic spectrum when it is excited by light.

Loukova et al., Chemical Physics Letters 329 (2000) 437 to 442, report phosphorescent excited states in the metallocenes of group IVa of the Periodic Table of the Elements. These complexes display luminescence when they are excited by light.

Yam et al., Journal of Organometallic Chemistry 548 (1997) 289 to 294, report the synthesis of zirconium thiolate complexes of the formula (η⁵-C₅H₅)₂Zr(SC₆H₄R-p)₂, where R is Cl, Me, or OMe. These complexes display luminescence in the visible region of the electromagnetic spectrum when excited by light.

In none of the abovementioned documents is the electroluminescence of zirconocene and hafnocene complexes mentioned.

Although compounds which display electroluminescence in the blue, red and green regions of the electromagnetic spectrum are already known, the provision of further compounds which can also be used as such as light-emitting layer is desirable. The term electroluminescence encompasses both electrofluorescence and electrophosphorescence.

It is therefore an object of the present application to provide a class of compounds which is suitable for use in various layers of an OLEDs, in particular to provide a compound which is suitable for electroluminescence in the blue, red and green regions of the electromagnetic spectrum, thus making the production of full-color displays possible.

This object is achieved by the use of metallocene complexes of metals of transition group 4 of the Periodic Table of the Elements in OLEDs.

The metallocene complexes can be used as emitter substance or as matrix material in the light-emitting layer of an OLED. Furthermore, it is possible to use the metallocene complexes as hole blockers, e.g. in a blocking layer for holes which is located between a light-emitting layer and an electron transport layer of the OLED. The metallocene complexes are preferably used as emitter molecules in the light-emitting layer.

As metals of transition group 4 of the Periodic Table of the Elements, preference is given to using Zr and Hf.

Particular preference is given to using uncharged zirconocene and hafnocene complexes of the formula (I)

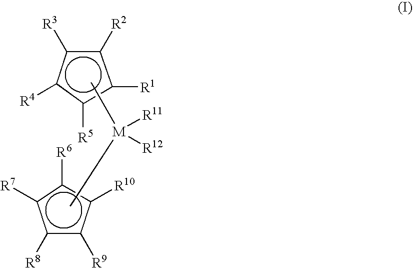

where the symbols have the following meanings:

| | |
|---|---|
| R¹, R², R³, R⁴, R⁵, | are each, independently of one another, H, |
| R⁶, R⁷, R⁸, R⁹, R¹⁰ | alkyl, aryl, alkoxy, hydroxy, aryloxy, |
| | halogen, CN, SCN, NO₂, CR¹⁷R¹⁸NR¹⁹R²⁰, |
| | CF₃; where R¹⁷, R¹⁸, R¹⁹, R²⁰ are each, |
| | independently of one another, H, alkyl or aryl; |
| or | |
| | two adjacent radicals together with the carbon |
| | atoms to which they are bound form a cyclic |
| | radical which may be saturated or unsaturated |
| | and substituted or unsubstituted and may |
| | contain one or more heteroatoms, preferably |
| | selected from N, O and S; |
| and/or | |
| R⁵ and R¹⁰ | together form a bridge having the general |
| | formula —(CR¹³R¹⁴)ₙ—, where R¹³ and R¹⁴ are |
| | each, independently of one another, H, alkyl |
| | or aryl, n is 1 or 2 and the radicals R |
| | and R¹⁴ in the n groups —(CR¹³R¹⁴)— can be |
| | identical or different and the carbon atom |
| | can be replaced by Si or B in |
| | one or more of the groups —(CR¹³R¹⁴)—; |
| R¹¹, R¹² | are each, independently of one another, alkyl, |
| | aryl, alkoxy, aryloxy, halogen, CN, SCN, CO, |
| | alkynyl, alkylamido, arylamido, |
| | trifluoromethanesulfonate or one of the |
| | radicals forms a μ-oxo bridge to a further |
| | zirconocene or hafnocene complex of the |
| | formula I; |
| or | |
| R¹¹ and R¹² | together form a bidentate ligand; |
| M | is Zr, Hf, in organic light-emitting |
| | diodes (OLEDs). |

The zirconocene or hafnocene complexes of the formula I are preferably used as matrix material or as emitter molecules in the light-emitting layer or as hole blockers. The use of zirconocene or hafnocene complexes of the formula I as emitter molecules in the light-emitting layer is particularly preferred.

For the purposes of the present application, the terms aryl radical or group, alkyl radical or group, alkoxy radical or group and aryloxy radical or group have the following meanings:

An aryl radical (or group) is a radical which has a basic skeleton of from 6 to 30 carbon atoms, preferably from 6 to 18 carbon atoms, and is made up of an aromatic ring or a plurality of fused aromatic rings. Suitable basic skeletons are, for example, phenyl, naphthyl, anthracenyl or phenanthrenyl. This basic skeleton can be unsubstituted (i.e. all carbon atoms which can be substituted bear hydrogen atoms) or can be substituted on one, more than one or all substitutable positions of the basic skeleton. Suitable substituents are, for example, alkyl radicals, preferably alkyl radicals having from 1 to 8 carbon atoms, particularly preferably methyl, ethyl, i-propyl or t-butyl, aryl radicals, preferably C₆-aryl radicals, which may in turn be substituted or unsubstituted, heteroaryl radicals, preferably heteroaryl radicals which contain at least one nitrogen atom, particularly preferably pyridyl radicals, alkenyl radicals, preferably alkenyl radicals containing one double bond, particularly preferably alkenyl radicals having one double bond and from 1 to 8 carbon atoms, or groups having a donor or acceptor action. Groups having a donor action are groups having a +I and/or +M effect, and groups having an acceptor action are groups having a −I and/or −M effect. Suitable groups having donor or acceptor action are halogen radicals, preferably F, Cl, Br, particularly preferably F, alkoxy radicals, carbonyl radicals, ester radicals, amine radicals, amide radicals, CH₂F groups, CHF₂ groups, CF₃ groups, CN groups, thio groups or SCN groups. The aryl radicals very particularly preferably bear substituents selected from the group consisting of methyl, F, Cl and alkoxy, or the aryl radicals are unsubstituted. The aryl radical or the aryl group is preferably a C₆-aryl radical which is optionally substituted by one of the abovementioned substituents. The C₆-aryl radical particularly preferably bears none, one or two of the abovementioned substituents, with a single substituent preferably being located in the para position relative to the further point of linkage of the aryl radical and, in the case of two substituents, these are each located in the meta position relative to the further point of linkage of the aryl radical. Very particular preference is given to the C₆-aryl radical being an unsubstituted phenyl radical.

An alkyl radical or an alkyl group is a radical having from 1 to 20 carbon atoms, preferably from 1 to 10 carbon atoms, particularly preferably from 1 to 8 carbon atoms. This alkyl radical can be branched or unbranched and may be interrupted by one or more heteroatoms, preferably N, O or S. Furthermore, this alkyl radical can be substituted by one or more of the substituents mentioned for the aryl groups. It is likewise possible for the alkyl radical to bear one or more aryl groups. In this case, all of the abovementioned aryl groups are suitable. Furthermore, the alkyl radical or the alkyl group can be a cyclic alkyl radical having from 3 to 10 ring atoms, preferably from 4 to 7 ring atoms. The ring atoms are carbon atoms of which one or more may be replaced by heteroatoms, preferably N, O or S. The cyclic alkyl radical can be substituted by the substituents mentioned with regard to the branched or unbranched alkyl radicals. The alkyl radicals are particularly preferably selected from the group consisting of methyl, ethyl, i-propyl, n-propyl, i-butyl, n-butyl, t-butyl, sec-butyl, i-pentyl, n-pentyl, sec-pentyl, neopentyl, n-hexyl, i-hexyl and sec-hexyl, cyclohexyl and cyclopentyl. Very particular preference is given to methyl, i-propyl, t-butyl and n-hexyl.

An alkoxy radical or an alkoxy group is a group of the general formula —OR¹⁵, where R¹⁵ is an alkyl radical as defined above. Preferred alkoxy radicals are thus alkoxy radicals selected from the group consisting of —Omethyl, —Oethyl, —Oⁱpropyl, —Oⁿpropyl, —Oⁱbutyl, —Oⁿbutyl, —O^{t}butyl, —O^{sec}butyl, —Oⁱpentyl, —Oⁿpentyl, —O^{sec}pentyl, —O^{neo}pentyl, —Oⁿhexyl, —Oⁱhexyl and —O^{sec}hexyl. Very particular preference is given to —Omethyl, —Oⁱpropyl, —O^{t}butyl and —Oⁿhexyl.

An aryloxy radical or an aryloxy group is a group of the general formula —OR¹⁶ where R¹⁶ is an aryl radical as defined above. As aryloxy radical, very particular preference is given to a radical of the group —Ophenyl.

An alkylthio radical or an alkylthio group is a group of the general formula —SR²¹, where R²¹ is an alkyl radical as defined above. Preferred alkylthio radicals are thus alkylthio radicals selected from the group consisting of —Smethyl, —Sethyl, —Sⁱpropyl, —Sⁿpropyl, —Sⁱbutyl, —Sⁿbutyl, —S^{t}butyl, —S^{sec}butyl, —Sⁱpentyl, —Sⁿpentyl, —S^{sec}pentyl, —S^{neo}pentyl, —Sⁿhexyl, —Sⁱhexyl and —S^{sec}hexyl. Very particular preference is given to —Smethyl, —Sⁱpropyl, —S^{t}butyl and —Sⁿhexyl.

An alkylthio radical or an arylthio group is a group of the general formula —SR²², where R²² is an aryl radical as defined above. As arylthio radical, very particular preference is given to a radical of the group —Sphenyl.

A halogen substituent is preferably F, Cl or Br, particularly preferably Cl or Br, very particularly preferably Cl.

A bidentate ligand is a ligand which has two coordination positions. Suitable bidentate ligands are, for example, bis(quinolinato), 2,2′-bipyridine, 2,2′-bipyridinedisulfonates and phenanthroline.

In a preferred embodiment of the present invention, R¹, R², R³, R⁴, R⁵, R⁶, R⁷, R⁸, R⁹ and R¹⁰ are each, independently of one another, H or alkyl, particularly preferably alkyl selected from the group consisting of methyl, ethyl, i-propyl, n-propyl, i-butyl, n-butyl, t-butyl, sec-butyl, i-pentyl, n-pentyl, sec-pentyl, neopentyl, n-hexyl, i-hexyl and sec-hexyl, especially preferably alkyl selected from the group consisting of methyl, i-propyl, t-butyl and n-hexyl; or halogen, preferably halogen selected from the group consisting of F, Cl and Br, very particularly preferably Cl.

Furthermore, in a preferred embodiment, two adjacent radicals together with the carbon atoms to which they are bound can form a cyclic radical, preferably a 5- or 6-membered ring, which can be saturated or unsaturated, with the term unsaturated cyclic radical also encompassing aromatic radicals, and can be substituted or unsubstituted. Suitable substituents are preferably selected from the group consisting of alkyl, aryl, alkoxy, hydroxy, aryloxy, halogen, CN, SCN and NO₂, with alkyl radicals being preferred. Suitable alkyl, aryl, alkoxy, aryloxy and halogen radicals have been mentioned above. However, the cyclic radical is very particularly preferably unsubstituted. For example, two adjacent radicals on one of the cyclic ligands of the compound of the formula I together with the carbon atom to which they are bound can form an ortho-phenylene radical, so that the cyclic ligand is an indenyl ligand. However, it is likewise possible for two pairs of adjacent radicals on a cyclic ligand of the compound of the formula I, e.g. R¹ and R² and also R³ and R⁴ together with the carbon atom to which they are bound, each to form an ortho-phenylene radical, so that the cyclic ligand is a fluorenyl ligand. In the following, all cyclic ligands of the compound of the formula I which are based on a central cyclopentadienyl radical will be referred to as cyclopentadienyl ligands.

Furthermore, R⁵ and R¹⁰ can together form a bridge of the general formula —(CR¹³R¹⁴)ₙ—, where R¹³ and R¹⁴ are each, independently of one another, preferably H or methyl and n is 1 or 2, particularly preferably 1. The carbon atom in the group —(CR¹³R¹⁴)— can be replaced by an Si atom which may bear the substituents R¹³ and R¹⁴ mentioned above. The bridge of the formula —(CR¹³R¹⁴)ₙ— is particularly preferably a bridge of the formula —(CH₃)₂C—, —(CH₂)₂— or —(CH₃)₂Si—.

Particular preference is given to the radicals R¹ and R⁶, R² and R⁷, R³ and R⁸, R⁴ and R⁹ and also R⁵ and R⁶ being in each case identical. This means that both cyclopentadienyl ligands in the formula I have the same substitution pattern.

The radicals R¹¹ and R¹² are each, independently of one another, alkyl, aryl, alkoxy, aryloxy, halogen, CN, SCN, alkylthio, arylthio, CO, alkynyl, alkylamido, arylamido, trifluoromethanesulfonate, or one of the radicals R¹¹ and R¹² forms a μ-oxo bridge to a further zirconocene or hafnocene complex of the formula I. Preferred alkyl, aryl, alkoxy, aryloxy, alkylthio, arylthio and halogen radicals have been mentioned above. Preference is given to R¹¹ and R¹² each being, independently of one another, aryl, alkoxy or halogen. Very particularly preferred radicals R¹¹ and R¹² are selected from the group consisting of CH₃, OCH₃ and Cl. The radicals R¹¹ and R¹² are especially preferably identical. Furthermore, R¹¹ and R¹² can together form a bidentate ligand. Suitable bidentate ligands have been mentioned above. Very particular preference is given to R¹¹ and R¹² each being Cl.

In a preferred embodiment, the present invention provides for the use of compounds of the formula I in which the symbols have the following meanings:

| | |
|---|---|
| R¹, R², R³, R⁴, R⁵, | are each, independently of one another, H, |
| R⁶, R⁷, R⁸, R⁹, R¹⁰ | alkyl, aryl or halogen; |
| or | |
| | two adjacent radicals together with the |
| | carbon atoms to which they are bound form |
| | an ortho-phenylene radical; |
| and/or | |
| R⁵ and R¹⁰ | together form a bridge of the general |
| | formula —(CR¹³R¹⁴)ₙ—, where R¹³ |
| | and R¹⁴ are each methyl and n is 1 and the |
| | carbon atom may be replaced by Si; |
| R¹¹, R¹² | are each, independently of one another, |
| | alkyl, alkoxy, alkylthio, arylthio or |
| | halogen. |

Preferred radicals R¹, R², R³, R⁴, R⁵, R⁶, R⁷, R⁸, R⁹ and R¹⁰ and preferred radicals R¹¹, R¹² and R¹³ and R¹⁴ have been mentioned above.

Especially preferred zirconocene and hafnocene complexes of the formula I are shown below, with M being Zr or Hf and rac denoting the racemic form of the respective complex and meso denoting the meso form of the complex.

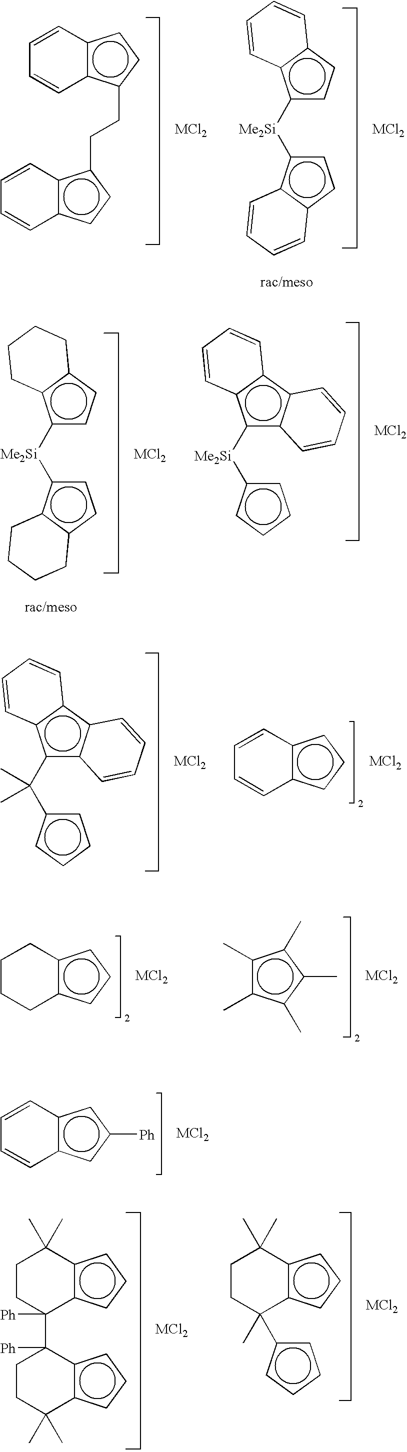

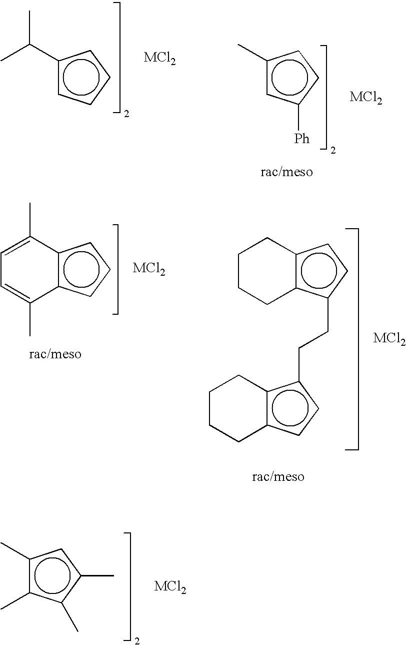

The abovementioned uncharged zirconocene and hafnocene complexes are highly suitable as emitter molecules in organic light-emitting diodes (OLEDs). Simple variations of the ligands make it possible to provide zirconocene and hafnocene complexes which display electroluminescence in the red, green and, in particular, blue regions of the electromagnetic spectrum. The uncharged zirconocene and hafnocene complexes used according to the invention are therefore suitable for use in industrially usable full-color displays.

The zirconocene and hafnocene complexes are prepared by methods known to those skilled in the art. Some of the zirconocene and hafnocene complexes used according to the invention are also commercially available.

A customary method of preparation is, for example, deprotonation of the ligand precursors corresponding to the cyclopentadienyl ligands of the compounds of the formula I and subsequent, generally in-situ, reaction with suitable zirconium- or hafnium-containing metal complexes. The suitable zirconium- or hafnium-containing metal complexes are generally commercially available or can be prepared by methods known to those skilled in the art and preferably contain radicals of the groups R¹¹ and R¹². Preferred zirconium- or hafnium-containing metal complexes are thus, for example, ZrCl₄, HfCl₄, the THF adducts of ZrCl₄ and HfCl₄, CpZrCl₃ and CpHfCl₃.

As an alternative, the ligand precursors corresponding to the cyclopentadienyl ligands of the compounds of the formula I can also be reacted with zirconium- or hafnium-containing bases, for example Zr(NEt₂)₄ or Hf(NEt₂)₄, using methods known to those skilled in the art.

Suitable ligand precursors which lead to the cyclopentadienyl ligands of the zirconocene and hafnocene complexes of the formula I are known to those skilled in the art and are commercially available or can be prepared by methods known to those skilled in the art.

If deprotonation of the ligands is carried out, this can be effected by means of alkali metals, in particular in finely divided form, basic metalates, basic anions such as metal acetates, acetylacetonates or alkoxides or external bases such as KO^{t}Bu, NaO^{t}Bu, LiO^{t}Bu, NaH, metal alkyls such as butyllithium, methyllithium, silylamides, lithium hexamethyldisilazide and phosphazene bases.

The reaction is preferably carried out in a solvent. Suitable solvents are aprotic solvents which are known to those skilled in the art and are preferably selected from aromatic and aliphatic solvents. Particular preference is given to using aromatic solvents such as toluene and benzene, ethers such as tetrahydrofuran, tert-butyl ether and tert-butyl methyl ether, and also halogenated hydrocarbons such as methylene chloride.

The molar ratio of zirconium- or hafnium-containing metal complex used to ligand precursor used is preferably from 0.7:2.0 to 1.5:2.0, particularly preferably from 0.9:2.0 to 1.1:2, very particularly preferably 1:2, in the case of ligands which do not have a bridge. In the case of ligands which have a bridge, the molar ratio is preferably from 0.7:1.0 to 1.5:1.0, particularly preferably from 0.9:1.0 to 1.1:1.0, very particularly preferably 1:1.

The reaction is generally carried out at temperatures of from −100° C. to +200° C., preferably from −100° C. to +100° C., particularly preferably from −78° C. to +50° C.

The reaction time depends on the desired zirconocene or hafnocene complex and is generally from 1 hour to 50 hours, preferably from 2 hours to 30 hours, particularly preferably from 5 hours to 25 hours.

The resulting zirconocene or hafnocene complex of the formula I is worked up by methods known to those skilled in the art. For example, the zirconocene or hafnocene complex formed is precipitated from the reaction solution by means of a nonpolar solvent, e.g. n-pentane or n-hexane, filtered, washed, for example with the solvent used for the precipitation, and subsequently dried. Highly pure zirconocene or hafnocene complexes are obtained by recrystallization, for example from dichloromethane, diethyl ether, dichloroethane or mixtures thereof.

The zirconocene and hafnocene complexes of the formula I used according to the invention are highly suitable as emitter substances since they display emission (electroluminescence) in the visible region of the electromagnetic spectrum. The zirconocene and hafnocene complexes used according to the invention as emitter substances make it possible to provide compounds which have electroluminescence in the red, green and blue regions of the electromagnetic spectrum. The zirconocene and hafnocene complexes used according to the invention as emitter substances thus make it possible to provide industrially usable full-color displays. Furthermore, the zirconocene and hafnocene complexes are suitable as hole blockers, for example in a blocking layer for holes which is located between the light-emitting layer and an electron transport layer of an OLED. The use of the zirconocene and hafnocene complexes used according to the invention in the various layers is dependent on the position of the HOMO of the metallocene complexes and thus on the substitution pattern of the metallocene complexes.

A particular property of the zirconocene and hafnocene complexes of the formula I is that, in the solid state, they display luminescence, particularly preferably electroluminescence, in the visible region of the electromagnetic spectrum. These complexes which luminescence in the solid state can be used as such, i.e. without further additives, as emitter substances in OLEDs. This makes it possible to produce an OLED comprising a light-emitting layer without complicated covaporization of a matrix material with the emitter substance being necessary.

The present invention therefore further provides organic light-emitting diodes (OLEDs) comprising at least one zirconocene complex and/or at least one hafnocene complex of the formula I.

Organic light-emitting diodes are basically made up of a plurality of layers:

1. Anode

2. Hole transport layer

3. Light-emitting layer

4. Electron transport layer

5. Cathode

The zirconocene and/or hafnocene complexes can be used in various layers of the OLED, depending on the position of their HOMO; for example, the zirconocene and/or hafnocene complexes can be used as hole blockers in a blocking layer for holes or as emitter molecules in the light-emitting layer.

They are preferably used as emitter molecules in the light-emitting layer. The present application therefore further provides a light-emitting layer comprising at least one zirconocene and/or at least one hafnocene complex. Preferred zirconocene and hafnocene complexes have been mentioned above.

The zirconocene and hafnocene complexes used according to the invention can be present as such, without further additives, in the light-emitting layer. However, it is likewise possible for further compounds to be present in addition to the zirconocene and hafnocene complexes used according to the invention in the light-emitting layer. For example, a fluorescent dye can be present in order to alter the emission color of the zirconocene or hafnocene complex used as emitter molecule. Furthermore, a diluent material can be used. This diluent material can be a polymer, for example poly(N-vinylcarbazole) or polysilane. However, the diluent material can likewise be a small molecule, for example 4,4′-N,N′-dicarbazolylbiphenyl (CBP), tetraarylsilane or tertiary aromatic amines. If a diluent material is used, the proportion of the platinum(II) complexes used according to the invention in the light-emitting layer is generally less than 20% by weight, preferably from 3 to 10% by weight. The zirconocene and/or hafnocene complexes are preferably used as such, thus avoiding complicated covaporization of the zirconocene and/or hafnocene complexes with a matrix material (diluent material or fluorescent dye). For this purpose, it is essential that the zirconocene and hafnocene complexes luminescence in the solid state. The zirconocene and hafnocene complexes display luminescence in the solid state. The light-emitting layer therefore preferably comprises at least one zirconocene and/or hafnocene complex and no matrix material selected from diluent material and fluorescent dye.

The present invention further provides, in a preferred embodiment, a light-emitting layer consisting of at least one zirconocene and/or at least one hafnocene complex. Preferred complexes have been mentioned above.

The abovementioned individual layers of the OLED can in turn be made up of 2 or more layers. For example, the hole transport layer can be made up of a layer into which holes are injected from the electrode and a layer which transports the holes away from the hole injection layer to the light-emitting layer. The electron transport layer can likewise consist of a plurality of layers, for example a layer into which electrons are injected by the electrode and a layer which receives electrons from the electron injection layer and transports them to the light-emitting layer.

These layers are each selected according to factors such as energy level, heat resistance and charge carrier mobility and also energy difference between the layers mentioned and the organic layers or the metal electrodes. A person skilled in the art will be able to select the structure of the OLEDs in such a way that it is optimally matched to the zirconocene and/or hafnocene complexes used according to the invention as emitter substances.

To obtain particularly efficient OLEDs, the HOMO (highest occupied molecular orbital) of the hole transport layer should be matched to the work function of the anode and the LUMO (lowest unoccupied molecular orbital) of the electron transport layer should be matched to the work function of the cathode.

The present invention further provides an OLED comprising at least one light-emitting layer according to the invention. The further layers in the OLED can be made up of any material which is customarily used in such layers and is known to those skilled in the art.

The anode (1) is an electrode which provides positive charge carriers. It can, for example, be made up of materials comprising a metal, a mixture of various metals, a metal alloy, a metal oxide or a mixture of various metal oxides. As an alternative, the anode can be a conductive polymer. Suitable metals include the metals of groups Ib, IVa, Va and Via of the Periodic Table of the Elements and the transition metals of group VIII. If the anode is to be transparent to light, use is generally made of mixed metal oxides of groups IIb, IIIb and IVb of the Periodic Table of the Elements, for example indium-tin oxide (ITO). It is likewise possible for the anode (1) to comprise an organic material, for example polyaniline, as described, for example, in Nature, vol. 357, pages 477 to 479 (Jun. 11, 1992). At least one of the anode or cathode should be at least partially transparent to enable the light produced to be emitted.

Suitable hole transport materials for layer (2) of the OLEDs of the invention are disclosed, for example, in Kirk-Othmer Encyclopedia of Chemical Technology, 4th edition, vol. 18, pages 837 to 860, 1996. Both hole-transporting molecules and polymers can be used as hole transport material. Customarily used hole-transporting molecules are selected from the group consisting of 4,4′-bis[N-(1-naphthyl)-N-phenylamino]biphenyl (α-NPD), N,N′-diphenyl-N,N′-bis-(3-methylphenyl)-[1,1′-biphenyl]-4,4′-diamine (TPD), 1,1-bis[(di-4-tolylamino)-phenyl]cyclohexane (TAPC), N,N′-bis(4-methylphenyl)-N,N′-bis(4-ethylphenyl)-[1,1′-(3,3′-dimethyl)biphenyl]-4,4′-diamine (ETPD), tetrakis(3-methylphenyl)-N,N,N′,N′-2,5-phenylenediamine (PDA), α-phenyl-4-N,N-diphenylaminostyrene (TPS), p-(diethylamino)benzaldehyde diphenylhydrazone (DEH), triphenylamine (TPA), bis[4-(N,N-diethylamino)-2-methylphenyl)](4-methylphenyl)methane (MPMP), 1-phenyl-3-[p-(diethylamino)styrene]-5-[p-(diethylamino)phenyl]-pyrazoline (PPR or DEASP), 1,2-trans-bis(9H-carbazol-9-yl)cyclobutane (DCZB), N,N,N′,N′-tetrakis(4-methylphenyl)-(1,1′-biphenyl)-4,4′-diamine (TTB) and porphyrin compounds such as copper phthalocyanines. Customarily used hole-transporting polymers are selected from the group consisting of polyvinylcarbazoles, (phenylmethyl)polysilanes and polyanilines. It is likewise possible to obtain hole-transporting polymers by doping polymers such as polystyrene and polycarbonate with hole-transporting molecules. Suitable hole-transporting molecules are the molecules mentioned above.

Suitable electron-transporting materials for layer (4) of the OLEDs of the invention comprise metals chelated with oxinoid compounds, e.g. tris(8-quinolinolato)aluminum (Alq₃), compounds based on phenanthroline, e.g. 2,9-dimethyl-4,7-diphenyl-1,10-phenanthroline (DDPA) or 4,7-diphenyl-1,10-phenanthroline (DPA), and azole compounds such as 2-(4-biphenylyl)-5-(4-t-butylphenyl)-1,3,4-oxadiazole (PBD) and 3-(4-biphenylyl)-4-phenyl-5-(4-t-butylphenyl)-1,2,4-triazole (TAZ). The layer (4) can serve either to aid electron transport or as a buffer layer or barrier layer to avoid quenching of the exciton at the boundaries of the layers of the OLED. The layer (4) preferably improves the mobility of the electrons and reduces quenching of the exciton.

The cathode (5) is an electrode which serves to introduce electrons or negative charge carriers. The cathode can be any metal or nonmetal which has a lower work function than the anode. Suitable materials for the cathode are selected from the group consisting of alkali metals of group Ia, for example Li, Cs, alkaline earth metals of group IIa, metals of group IIb of their Periodic Table of the Elements, and the rare earth metals and the lanthanides and actinides. Metals such as aluminum, indium, calcium, barium, samarium and magnesium and combinations thereof can also be used. Furthermore, lithium-containing organometallic compounds or LiF can be applied between the organic layer and the cathode to reduce the operating voltage.

The OLED of the present invention can further comprise additional layers which are known to those skilled in the art. For example, a further layer can be applied between the layer (2) and the light-emitting layer (3) and serves to aid transport of the positive charge and/or match the band gap of the layers to one another. As an alternative, this further layer can serve as protective layer. In an analogous way, additional layers can be present between the light-emitting layer (3) and the layer (4) in order to aid transport of the negative charge and/or match the band gap between the layers to one another. As an alternative, this layer can serve as protective layer.

In a preferred embodiment, the OLED of the invention contains, in addition to the layers (1) to (5), at least one of the following further layers:
a hole injection layer between the anode (1) and the hole transport layer (2);
a blocking layer for electrons between the hole transport layer (2) and the light-emitting layer (3);
a blocking layer for holes between the light-emitting layer (3) and the electron transport layer (4);
an electron injection layer between the electron transport layer (4) and the cathode (5).

A person skilled in the art will know how to select suitable materials (for example on the basis of electrochemical studies). Suitable materials for the individual layers are known to those skilled in the art and are disclosed, for example, in WO 00/70655.

Furthermore, each of the abovementioned layers of the OLED of the invention can be made up of two or more layers. It is also possible for one or all of the layers (1), (2), (3), (4) and (5) to be surface-treated in order to increase the efficiency of charge carrier transport. The choice of materials for each of the layers mentioned is preferably made so as to obtain an OLED having a high efficiency.

The OLED of the invention can be produced by methods known to those skilled in the art. In general, the OLED is produced by successive vapor deposition of the individual layers on a suitable substrate. Suitable substrates are, for example, glass or polymer films. The vapor deposition can be carried out using customary techniques such as thermal vaporization, chemical vapor deposition and others. In an alternative process, the organic layers can be applied from solutions or dispersions in suitable solvents, with coating techniques known to those skilled in the art being employed.

In general, the various layers have the following thicknesses: anode (2) from 500 to 5000 Å, preferably from 1000 to 2000 Å; hole transport layer (3) from 50 to 1000 Å, preferably from 200 to 800 Å, light-emitting layer (4) from 10 to 1000 Å, preferably from 100 to 800 Å, electron transport layer (5) from 50 to 1000 Å, preferably from 200 to 800 Å, cathode (6) from 200 to 10 000 Å, preferably from 300 to 5000 Å. The position of the recombination zone of holes and electrons in the OLED of the invention and thus the emission spectrum of the OLED can be influenced by the relative thickness of each layer. This means that the thickness of the electron transport layer should preferably be selected so that the electron/hole recombination zone is located in the light-emitting layer. The ratio of the thicknesses of the individual layers of the OLED is dependent on the materials used. The thicknesses of any additional layers used are known to those skilled in the art.

The use of the zirconocene and hafnocene complexes used according to the invention in the light-emitting layer of the OLEDs of the invention makes it possible to obtain OLEDs having a high efficiency. The efficiency of the OLEDs of the invention can also be improved by optimizing the other layers. For example, highly efficient cathodes such as Ca, Ba or LiF can be used. Shaped substrates and new hole transport materials which effect a reduction in the operating voltage or an increase in the quantum efficiency can likewise be used in the OLEDs of the invention. Furthermore, additional layers can be present in the OLEDs to adjust the energy level of the various layers and to aid electroluminescence.

The OLEDs of the invention can be used in all devices in which electroluminescence is useful. Suitable devices are preferably selected from among stationary and mobile VDUs. Stationary VDUs are, for example, VDUs of computers, televisions, VDUs in printers, kitchen appliances and advertising signs, lighting and information signs. Mobile VDUs are, for example, VDUs in cellphones, laptops, vehicles and destination displays on buses and trains.

The zirconocene and hafnocene complexes used according to the invention can also be used in OLEDs having an inverse structure. In these inverse OLEDs, the zirconocene and hafnocene complexes are once again preferably used in the light-emitting layer, particularly preferably as light-emitting layer without further additives. The structure of inverse OLEDs and the materials customarily used therein are known to those skilled in the art.

### EXAMPLES

### Example 1

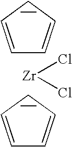

Zirconocene dichloride is commercially available.

UV/Vis (powder): λ_{max, em}=451 nm

### Example 2

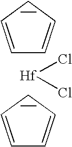

Hafnocene dichloride is commercially available.

UV/Vis (powder): λ_{max, em}=449 nm

### Example 3

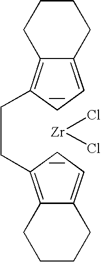

rac-Ethylenebis(4,5,6,7-tetrahydro-1-indenyl)zirconium dichloride is commercially available.

UV/Vis (powder): λ_{max, em}=458 nm

1-11. (canceled)

12. An organic light-emitting diode (OLED) comprising at least one zirconocene and hafnocene complex of formula I 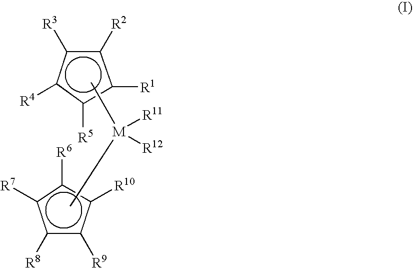
wherein the symbols have the following meanings:

| | |
|---|---|
| R¹, R², R³, R⁴, R⁵, | are each, independently of one another, |
| R⁶, R⁷, R⁸, R⁹, R¹⁰ | H, alkyl, aryl, alkoxy, hydroxy, aryloxy, |
| | halogen, CN, SCN, NO₂, CR¹⁷R¹⁸NR¹⁹R²⁰, |
| | CF₃; where R¹⁷, R¹⁸, R¹⁹, R²⁰ are each, |
| | independently of one another, H, alkyl |
| | or aryl; |
| or | |
| | two adjacent radicals together with the |
| | carbon atoms to which they are bound form |
| | a cyclic radical which may be saturated or |
| | unsaturated and substituted or unsubstituted |
| | and may contain one or more heteroatoms; |
| and/or | |
| R⁵ and R¹⁰ | together form a bridge having the general |
| | formula —(CR¹³R¹⁴)ₙ—, where R¹³ and |
| | R¹⁴ are each, independently of one another, |
| | H, alkyl or aryl, n is 1 or 2 and the |
| | radicals R¹³ and R¹⁴ in the n groups |
| | —(CR¹³R¹⁴)— can be identical or |
| | different and the carbon atom can be |
| | replaced by Si or B in one or more of the |
| | groups —(CR¹³R¹⁴)—; |
| R¹¹, R¹² | are each, independently of one another, |
| | alkyl, aryl, alkoxy, aryloxy, halogen, |
| | CN, SCN, CO, alkynyl, alkylthio, |
| | arylthio, alkylamido, arylamido, |
| | trifluoromethanesulfonate or one of |
| | the radicals forms a μ-oxo bridge to a |
| | further zirconocene or hafnocene complex |
| | of the formula I; |
| or | |
| R¹¹ and R¹² | together form a bidentate ligand; and |
| M | is Zr or Hf. |

13. The organic light-emitting diode according to claim 12, wherein

| | |
|---|---|
| R¹, R², R³, R⁴, R⁵, | are each, independently of one another, H, |
| R⁶, R⁷, R⁸, R⁹, R¹⁰ | alkyl, aryl or halogen; |
| or | |
| | two adjacent radicals together with the |
| | carbon atoms to which they are bound form an |
| | ortho-phenylene radical; |
| and/or | |
| R⁵ and R¹⁰ | together form a bridge of the general |
| | formula —(CR¹³R¹⁴)ₙ—, where R¹³ and R¹⁴ are |
| | each methyl and n is 1 and the carbon |
| | atom may be replaced by Si; and |
| R¹¹, R¹² | are each, independently of one another, |
| | alkyl, alkoxy, alkylthio, arylthio or halogen. |

14. The organic light-emitting diode according to claim 12, wherein the zirconocene and hafnocene complexes are selected from the group consisting of 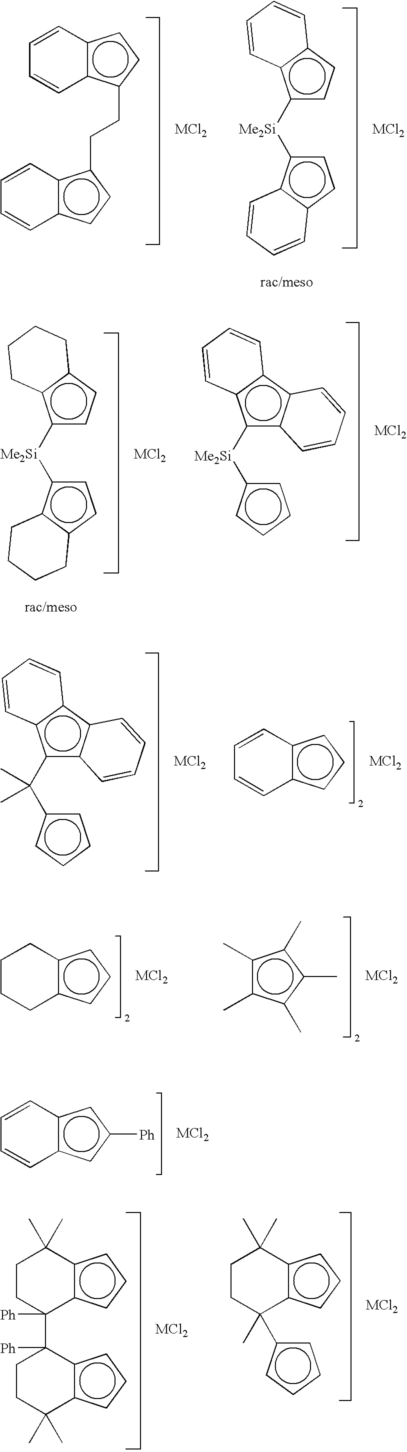 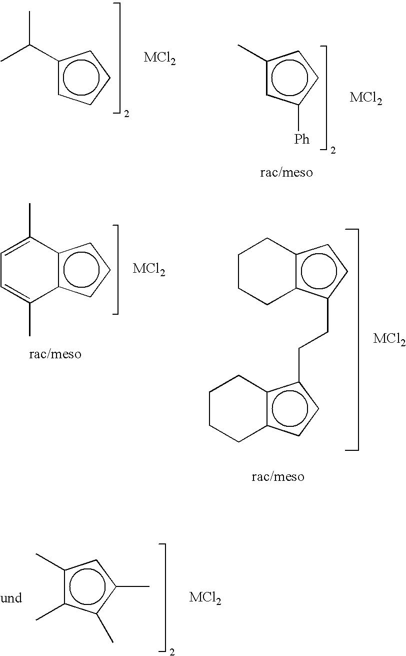
wherein M is Zr or Hf and rac denotes the racemic form of the respective complex and meso denotes the meso form of the respective metal complex.

15. The organic light-emitting diode according to claim 12, wherein the metallocene complexes are used as emitter molecules in the OLEDs.

16. A light-emitting layer comprising at least one zirconocene and/or at least one hafnocene complex according to claim 12.

17. A light-emitting layer consisting of at least one zirconocene and/or at least one hafnocene complex according to claim 12.

18. An OLED comprising the light-emitting layer according to claim 16.

19. A device selected from the group consisting of stationary VDUs such as VDUs of computers, televisions, VDUs in printers, kitchen appliances and advertising signs, lighting, information signs and mobile VDUs such as VDUs in cellphones, laptops, color televisions and destination displays on buses and trains comprising the OLED according to claim 12.
